(19) United States
(12) Patent Application Publication
(10) Pub. No.: US 2015/0069544 A1
(43) Pub. Date: Mar. 12, 2015

(54) MAGNETO-RESISTIVE ELEMENT

(71) Applicants: Makoto NAGAMINE, Seoul (KR); Youngmin EEH, Seoul (KR); Koji UEDA, Seoul (KR); Daisuke WATANABE, Seoul (KR); Kazuya SAWADA, Seoul (KR); Toshihiko NAGASE, Seoul (KR)

(72) Inventors: Makoto NAGAMINE, Seoul (KR); Youngmin EEH, Seoul (KR); Koji UEDA, Seoul (KR); Daisuke WATANABE, Seoul (KR); Kazuya SAWADA, Seoul (KR); Toshihiko NAGASE, Seoul (KR)

(21) Appl. No.: 14/158,532

(22) Filed: Jan. 17, 2014

Related U.S. Application Data
(60) Provisional application No. 61/874,612, filed on Sep. 6, 2013.

(51) Int. Cl. H01L 43/02; H01L 43/10; H01L 27/22

(52) U.S. Cl. CPC H01L 43/02; H01L 27/222; H01L 43/10
USPC 257/421

(57) ABSTRACT

According to one embodiment, magneto-resistive element, includes a first ferromagnetic layer formed on an underlying substrate, a tunnel barrier layer formed on the first ferromagnetic layer, a second ferromagnetic formed on the tunnel barrier layer and a cap layer formed on the second ferromagnetic layer, and a surface tension of the cap layer is equal to or less than that of the second ferromagnetic layer.

### CROSS-REFERENCE TO RELATED APPLICATIONS

This application claims the benefit of U.S. Provisional Application No. 61/874,612, filed Sep. 6, 2013, the entire contents of which are incorporated herein by reference.

### FIELD

Embodiments described herein relate generally to a magneto-resistive element comprising a cap layer.

### BACKGROUND

Recently, large-capacity magneto-resistive random access memories (MRAMs) have been attracting attention, with expectations. An MRAM employs a magnetic tunnel junction (MTJ) element which exploits the tunnel magneto-resistive (TMR) effect. Each MTJ element in an MRAM comprises two ferromagnetic layers (CoFeB) between which a tunnel barrier layer (MgO) is interposed, one of the two ferromagnetic layers being a magnetization fixed layer (reference layer) in which the direction of magnetization is fixed and so does not change, and the other being a magnetization free layer (memory layer) the direction of magnetization of which is capable of being easily changed. The states in which the directions of magnetization of the reference layer and memory layer are mutually parallel and anti-parallel are respectively defined as binary 0 and binary 1 on the basis of which data can be stored.

More specifically, when the directions of magnetization of the reference and memory layers are parallel, the resistance of the tunnel barrier layer (that is, the barrier resistance) is low, and the tunnel current is greater than that when the directions of magnetization are antiparallel. The MR ratio is defined as: resistance in antiparallel state-resistance in parallel state/resistance in parallel state. Because stored data is read by detecting differences in resistance due to the TMR effect, it is preferable when reading data that the ratio of resistive difference (MR ratio) by the TMR effect should be high.

### BRIEF DESCRIPTION OF THE DRAWINGS

FIGS. 1A to 10 are schematic diagrams illustrating the operation of embodiments;

FIG. 2 is a view of an example of a surface tension in each layer of a magneto-resistive element;

FIG. 3 is a cross sectional view showing a basic structure of an MTJ element;

FIG. 4 is a diagram showing a relationship between the surface tension and standard electrode potential in each of various metal materials;

FIG. 5 is a cross sectional view showing a brief structure of the magneto-resistive elements of the embodiments; and

FIGS. 6A to 6H are cross sectional views of production steps of the magneto-resistive element shown in FIG. 4.

### DETAILED DESCRIPTION

In general, according to one embodiment, there is provided a magneto-resistance element comprising: a first ferromagnetic layer formed on an underlying substrate; a tunnel barrier layer formed on the first ferromagnetic layer; a second ferromagnetic layer formed on the tunnel barrier layer; a cap layer formed on the second ferromagnetic layer, wherein a surface tension of the cap layer is equal to or less than that of the second ferromagnetic layer.

According to the conventional method of manufacturing an MTJ element, Ta is formed as a cap layer immediately above a CoFeB ferromagnetic layer. It should be noted here that, this method, however, entails the following drawbacks. That is, since the surface tension of Ta is higher than that of CoFeB, Ta easily grow in an island shape on CoFeB, and a portion of the Ta layer grown to have an island shape sinks into CoFeB. Then, when a layer formed of CoFeB—MgO—CoeB is annealed to promote (001)-orientation, Ta easily diffuses into CoFeB. This causes the degradation of magnetic properties of CoFeB. As a result, a high MR ratio cannot be achieved. This embodiment has been proposed to solve the above-mentioned drawback, as a technique for obtaining a high MR ratio.

(Basic Principle of Embodiments)

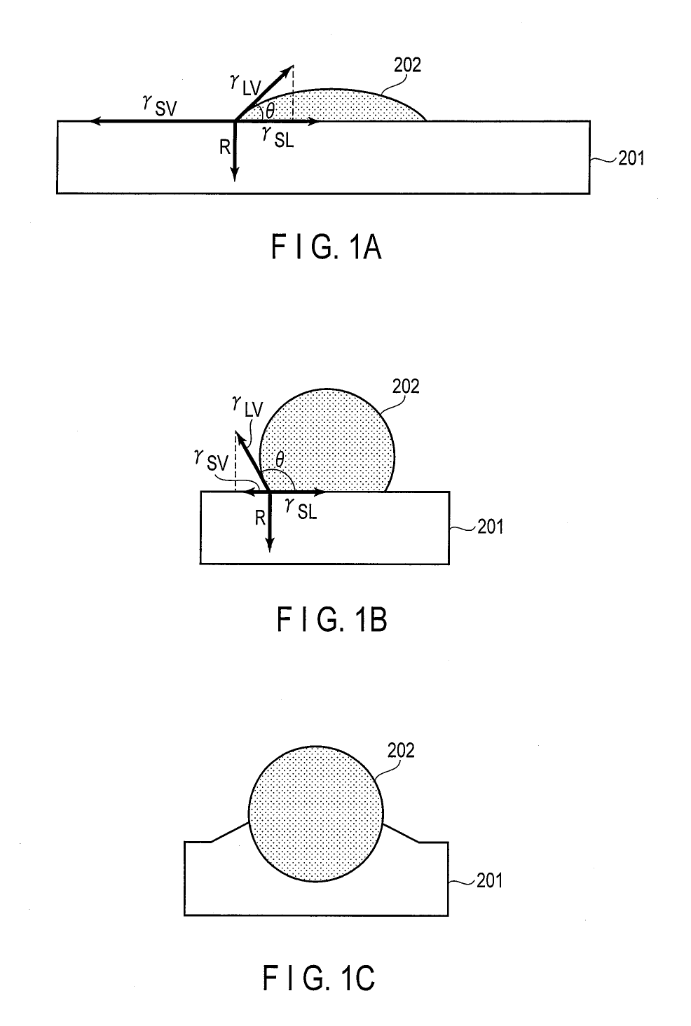

FIGS. 1A to 1C are schematic diagrams illustrating a state in which a liquid-like deposit layer 202 is formed on an underlying layer 201, to explain the operation of this embodiment.

FIG. 1A shows a case where surface tension of the deposit layer 202 is lower than that of the underlying layer 201. The figure illustrates a surface tension γ_{SV} of the underlying layer 201, a surface tension γ_{LV} of the deposit layer 202, an interface tension γ_{SL}, a resistance R and a contact angle θ. In this case, the contact angle θ is sufficiently small, and the deposit layer 202 is formed to be conformal. Even in the case where the surface tension of the deposit layer 202 is equal to that of the underlying layer 201, the deposit layer 202 is formed to be conformal.

FIG. 1B shows a case where the surface tension of the deposit layer 202 is higher than that of the underlying layer 201. In this case, the contact angle θ is large, and the deposit layer 202 grows in an island fashion. Further, as shown in FIG. 1C, the deposit layer 202 sink in the underlying layer 201, and with this structure, componential materials of the deposit layer can easily diffuse in the underlying layer 201.

In order to form the deposit layer 202, as a cap layer, to be conformal on the underlying layer 201, as a ferromagnetic layer, it suffices if the surface tension of the cap layer is set to be equal to or less than that of the underlying ferromagnetic layer.

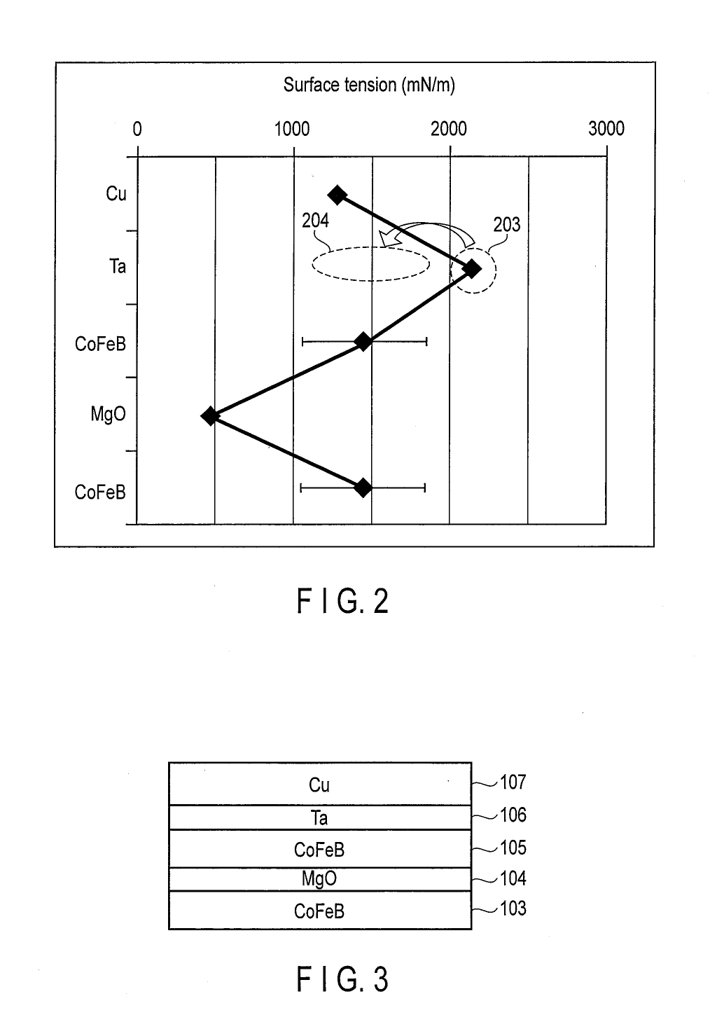

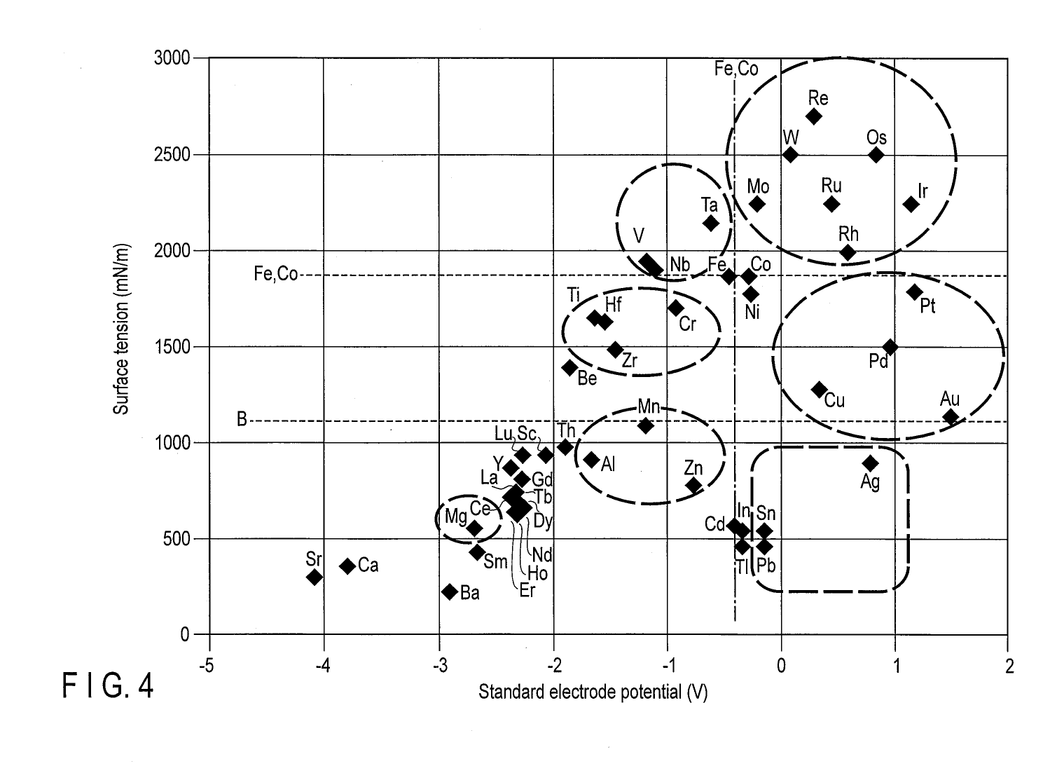

FIG. 2 illustrates the surface tension of each of various kinds of metal materials which constitute the MTJ element. The properties illustrated here are of an example of the MTJ element, in which a CoFeB layer (first ferromagnetic layer) 103, an MgO layer (tunnel barrier layer) 104, a CoFeB layer (second ferromagnetic layer) 105, a Ta layer (cap layer) 106 and a Cu layer (upper layer) 107 are stacked on the underlying layer as shown in FIG. 3.

A surface tension 203 of the Ta cap layer 106, which is located immediately above the CoFeB layer 105, is higher than that of CoFeB, and therefore it can easily grow in an island shape. In order to suppress the island-like growth, it suffices if the surface tension of the cap layer 106, which is located immediately above the CoFeB layer 105, is set within or lower than that indicated by reference numeral 204 in FIG. 2.

In general, the surface tension of an alloy of two kinds of metals falls in a range between that of an alloy having a higher surface tension and that of the other having a lower surface tension, and is determined by the composition of these metals. In the case of an alloy of three or more types of metals, the surface tension falls in a range between that of an alloy having the highest surface tension and that of the one having the lowest surface tension.

Therefore, in order to equalize the surface tension of the cap layer 106 with that of the underlying ferromagnetic layer, it suffices if the surface tension of the cap layer 106 is set higher than that of the element having the lowest surface tension among those constituting the underlying ferromagnetic layer, but lower than that of the element having the highest surface tension among those constituting the second ferromagnetic layer. Further, in order to reliably set the surface tension of the cap layer 106 lower than that of the underlying ferromagnetic layer, it suffices if the surface tension of the cap layer 106 is set lower than that of the element having the lowest surface tension among those constituting the underlying ferromagnetic layer.

For the prevention of the above-mentioned island-like growth shown in FIG. 1B, the upper limit of the surface tension of the cap layer 106 must be equal to or less than that of the element having the highest surface tension among those constituting its underlying ferromagnetic layer 105. On the other hand, the upper layer is formed further above the cap layer 106, and therefore if the surface tension of the cap layer 106 is excessively low, the island-like growth of the upper layer is enhanced. Therefore, in order to suppress the island-like growth of the upper layer, the surface tension of the cap layer 106 should not be set greatly lower than that of its underlying ferromagnetic layer 105, but should be equal to or slightly lower than the surface tension of the ferromagnetic layer 105. In order for this, the surface tension of the cap layer 106 should preferably set equal to or higher than that of the element having the lowest surface tension among those constituting the underlying ferromagnetic layer.

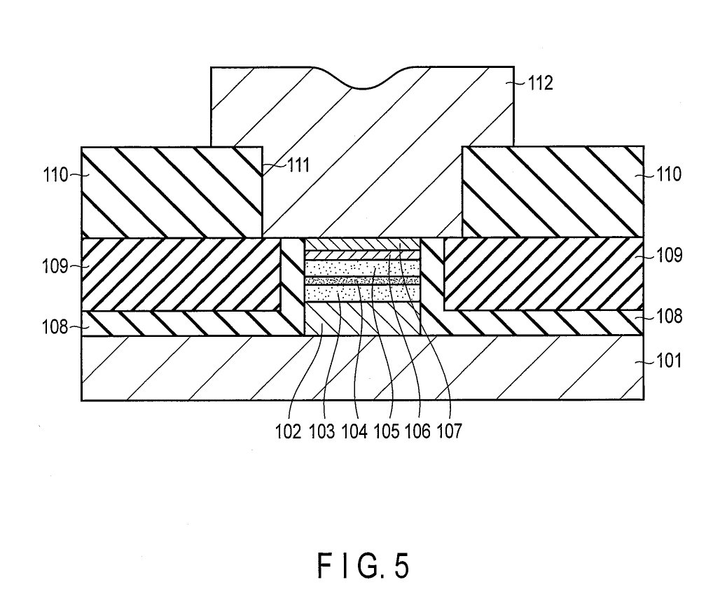

FIG. 4 is a diagram showing the relationship between the surface tension and standard electrode potential in each of various metal materials. For the suppression of the island-growth of the cap layer, a combination desirable for the materials of the cap layer can be selected from the vertical axis of FIG. 4.

When the cap layer 106 has a standard electrode potential lower than those of Fe and Co and also an appropriately adjusted surface tension, the cap layer 106 can supply electrons to the CoFeB layer 105 to charge it negative, thereby preventing oxidization of the interface between the CoFeB layer 105 and the tunnel barrier 104. Further, diffusion of the materials from the cap layer 106 to the CoFeB layer 105 can be suppressed, thereby preventing the degradation of the magnetic properties. Thus, a high MR ratio can be achieved.

On the other hand, when the cap layer 106 has a standard electrode potential higher than those of Fe and Co but has an appropriately adjusted surface tension, it is possible that the cap layer 106 captures electrons from the CoFeB layer 105 to charge it positive, thus oxidizing the interface between the CoFeB layer 105 and the tunnel barrier 104. However, the diffusion of the materials from the cap layer 106 to the CoFeB layer 105 can be suppressed, and therefore still, an MR ratio higher than those of the conventional techniques, can be achieved.

In addition, with regard to the standard electrode potentials of Fe and Co, a combination of a material having a higher potential than those and another material having a lower potential than those, can be employed as well. In general, a material having a standard electrode potential lower than those of Fe and Co, exhibits good magnetic properties but the thermal resistance thereof is low. On the other hand, a material having a standard electrode potential higher than those of Fe and Co, exhibits a good thermal resistance but the magnetic properties thereof are low. However, with an alloy of a material having a standard electrode potential lower than those of Fe and Co and another material having a standard electrode potential higher than those of Fe and Co, the thermal resistance can be improved while maintaining good magnetic properties. Such phenomena have been confirmed in tests carried out by the inventors of the embodiments.

Therefore, by selecting a combination desirable for the cap layer material not only from the vertical axis but also the horizontal axis of FIG. 4, further more excellent properties can be obtained.

From FIGS. 2 and 4, it can be understood that when CoFeB is used as the ferromagnetic layer, selection of preferable materials for setting the surface tension of the cap layer should be one of the followings:

(1) a single elemental metal having a surface tension lower than that of B or an alloy of such metals;

(2) a single elemental metal having a surface tension lower than those of Fe and Co but higher than that of B or an alloy of such metals;

(3) an alloy of a metal having a surface tension lower than those of Fe and Co but higher than that of B and another metal having a surface tension lower than that of B; and

(4) an alloy of a metal having a surface tension higher than those of Fe and Co and another metal having a surface tension lower than that of B.

More specifically, the materials of category (1) are elemental metals of Al, Mn, Zn, Mg, Ag, Sn and Pb and an alloy of a combination of any of these. More preferably, the material should be an alloy of one or more of Al, Mn, Zn and Mg and one or more of Ag, Sn and Pb.

The materials of category (2) are elemental metals of Ti, Hf, Cr, Zr, Pt, Pd, Cu and Au and an alloy of a combination of any of these. More preferably, the material should be an alloy of one or more of Ti, Hf, Cr and Zr and one or more of Pt, Pd, Cu and Au.

The materials of category (3) are alloys of one or more of Ti, Hf, Cr, Zr, Pt, Pd, Cu and Au and one or more of Al, Mn, Zn, Mg, Ag, Sn and Pb. More preferably, the material should be an alloy of one or more of Ti, Hf, Cr and Zr and one or more of Ag, Sn and Pb, or an alloy of one or more of Pt, Pd, Cu and Au and one or more of Al, Mn, Zn and Mg.

The materials of category (4) are alloys of one or more of Ta, V, Nb, W, Mo, Ru, Ir and Rh and one or more of Al, Mn, Zn, Mg, Ag, Sn and Pb. More preferably, the material should be an alloy of one or more of Ta, V and Nb and one or more of Ag, Sn and Pb, or an alloy of one or more of W, Mo, Ru, Ir and Rh and one or more of Al, Mn, Zn and Mg.

In the present embodiments, the above-listed materials are selected as the cap layer formed on the CoFeB ferromagnetic layer, and thus the cap layer can be formed conformally. Thus, the embodiments can contribute to the realization of an MTJ element having a high MR ratio.

The magneto-resistive element according to the embodiment and the manufacturing method thereof will now be explained in more detail.

### Embodiment

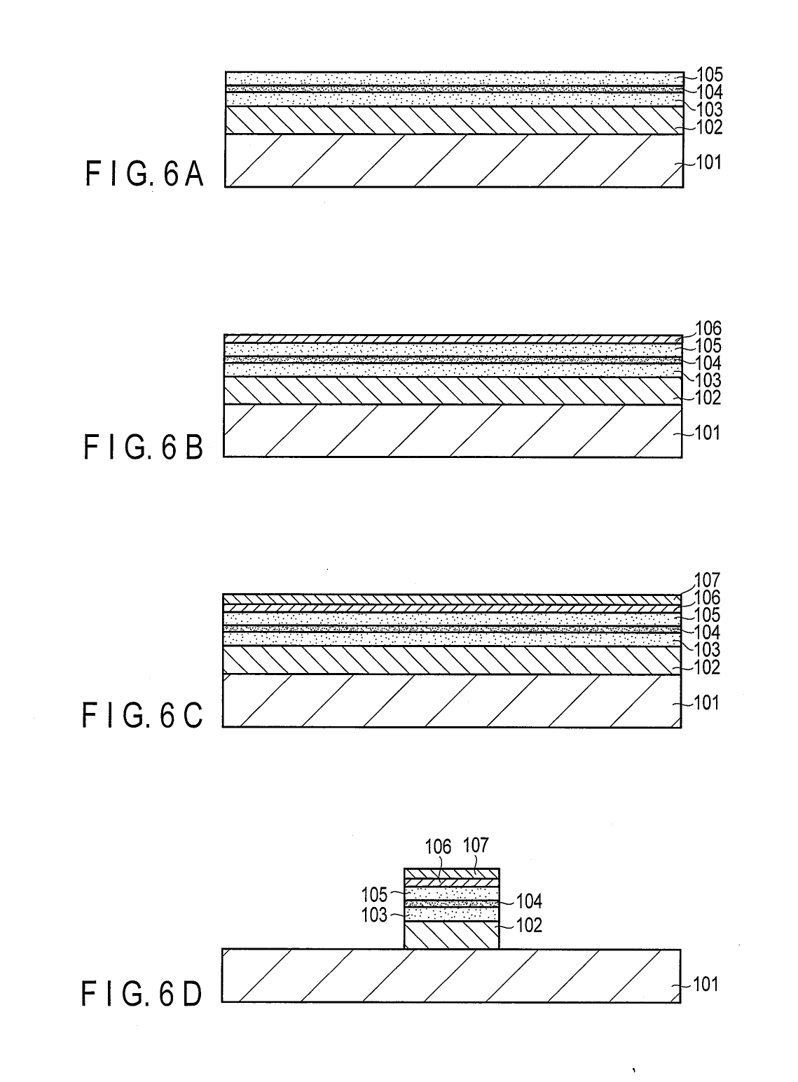

FIG. 5 is a cross section of a brief structure of a magneto-resistive element of this embodiment. The magneto-resistive element of this embodiment is an MTJ element used in an MRAM.

A lower wiring layer 101 of Ta or the like is formed on a substrate (not shown), and an underlying layer 102 of Ru or the like, a first ferromagnetic layer 103 comprising CoFeB, a tunnel barrier layer 104 comprising MgO, a second ferromagnetic layer 105 comprising CoFeB, a cap layer 106 and an upper layer 107 of Al, Cu or the like are stacked on the lower wiring layer. These stacked layer structural components are processed in an island shape.

Here, the cap layer 106 should only be selected from the materials explained above, and it is formed of, for example, an Al—Ni alloy.

An insulation layer 108 of SiN or the like is formed on side surfaces of the MTJ portion processed into the island shape and also on the underlying wiring layer 101 in order to protect the MTJ portion.

Further, an insulation layer 109 of SiO₂ or the like is formed on the side surfaces of the MTJ portion such as to interpose the insulation layer 108 between each side surface and itself, as it is embedded therein.

An insulation layer 110 of SiO₂ or the like is formed on the insulation layer 109 and the MTJ portion, and a contact hole 111 is formed in the insulation layer 110 to open a section above the MTJ portion. Then, an upper wiring layer 112 of Al, Cu or the like is formed on the insulation layer 110 to fill in the contact hole 11, and the upper wiring layer 112 is processed into a wiring pattern.

It should be noted here that although it is not shown in the figure, the magneto-resistive element of this embodiment has a configuration in which the element is disposed at each intersection of bit lines BL and word lines WL arranged to intersect with each other, and each element is configured to function as a memory cell of MRAM.

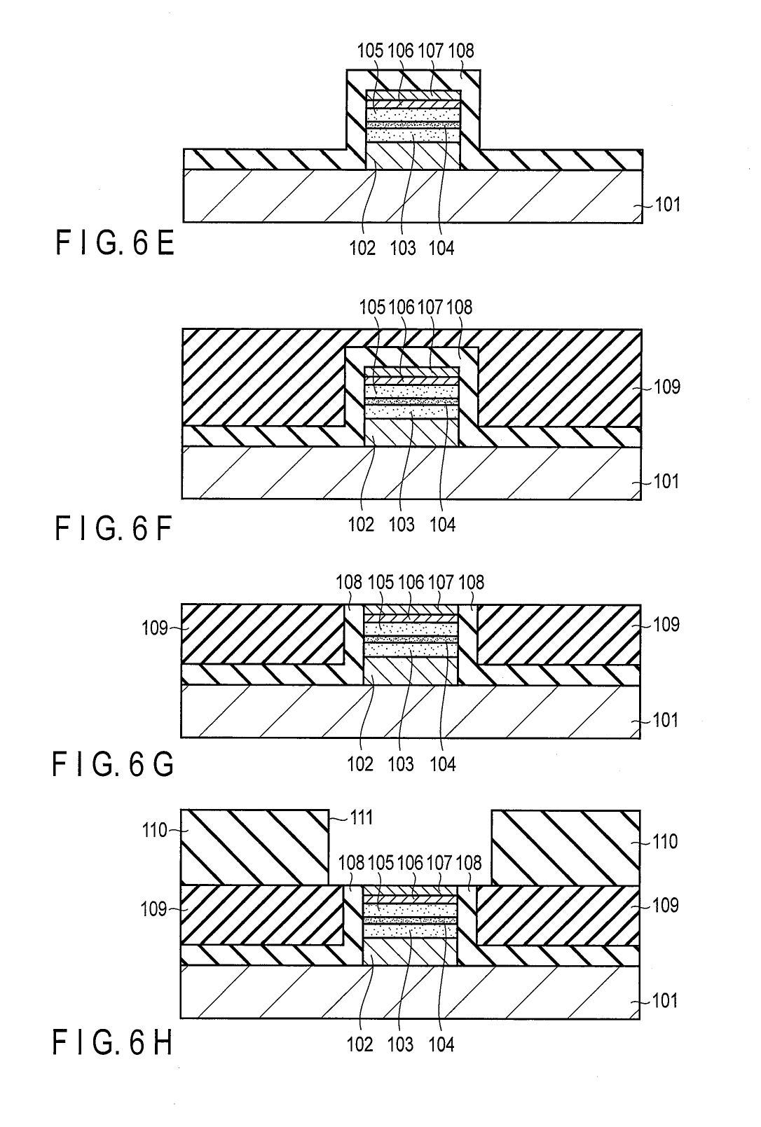

Next, a method of manufacturing a magneto-resistive element of the present embodiment will now be described with reference to FIGS. 6A to 6H.

First, as shown in FIG. 6A, on a lower wiring layer 101 of Ta or the like having a thickness of 5 nm, formed are an underlying layer 102 of Ru or the like having a thickness of 2 nm, a CoFeB layer (first ferromagnetic layer) 103 having a thickness of 1.5 nm, an MgO (tunnel barrier layer) 104 having a thickness of 1 nm, and a CoFeB (second ferromagnetic layer) 105 having a thickness of 1.5 nm. The underlying layer 102 may also function as a reference layer. The first ferromagnetic layer 103 may be used as a reference layer or memory layer.

The method of forming the tunnel barrier 104 may be any of the followings: direct sputtering of the target of oxidation by RF; post-oxidation of a metal layer by oxygen gas, oxygen plasma, oxygen radical or ozone, a molecular beam epitaxy (MBE) method, an atomic layer deposition (ALD) method, an molecular beam epitaxy (MBE) and a chemical vapor deposition (CVD), etc. Further, the method of forming the ferromagnetic layers 103 and 105 may be any of the sputtering, MBE and ALD methods.

Next, as shown in FIG. 6B, the alloy cap layer 106 to which the embodiment is applied is formed. More specifically, the cap layer 106 is formed of an Al—Ni alloy on the CoFeB ferromagnetic layer 105 by the sputtering method. As can be seen from FIG. 4, the surface tension of the cap layer 106 of the Al—Ni alloy is equal to or lower than that of the underlying CoFeB, and therefore the cap layer 106 is formed conformally on the ferromagnetic layer 105.

Next, as shown in FIG. 6C, the upper layer 107 of Al, Cu or the like is formed on the cap layer 106. The upper layer 107 may be used as an etching mask, a reference layer, a surface protection layer or an upper wiring connection layer. It should be noted that the surface tension of Al or Cu is equal to or lower than that of the Al—Ni alloy, and therefore the upper layer 107 is formed conformally on the cap layer 106.

Next, as shown in FIG. 6D, the upper layer 107, the cap layer 106, the second ferromagnetic layer 105, the tunnel barrier layer 104, the first ferromagnetic layer 103 and the underlying layer 102 are etched selectively in this order by, for example, the ion milling method, and thus the stacked structure portion comprising the underlying layer 102 to the upper layer 107 is processed into an island shape.

Subsequently, as shown in FIG. 6E, the insulation layer 108 configured to protect the MTJ portion in the next step is formed by, for example, the sputtering method, CVD method or ALD method. The insulation layer 108 is formed of, for example, SiN, SiOx, MgO and AlOx, on an upper surface and side surfaces of the MTJ portion and an exposed upper surface of the lower wiring layer 101.

Next, the lower wiring layer 101 is selectively etched by, for example, the reactive ion etching (RIE) method. Note that the processed section of the lower wiring layer 101 is located on, for example, the front side and further side of the page on FIG. 6E, and not shown. During the etching, the MTJ portion is protected by the insulation layer 108 shown in FIG. 6E.

Next, as shown in FIG. 6F, the insulation layer 109 is formed on the insulation layer 108 such as to bury the MTJ portion by, for example, the sputtering method or CVD method. The insulation layer 109 is formed of, for example, SiOx.

Next, as shown in FIG. 6G, the insulation layer is subjected to etchback by, for example, the chemical mechanical polishing (CMP) method or gas phase etching method, and thus an upper surface of the upper layer 107 of the MTJ portion is exposed.

Next, as shown in FIG. 6H, the insulation layer 110 is formed on the MTJ portion and the insulation layer 109, and thereafter, the contact hole 111 is formed in the upper section of the MTJ portion by, for example, the RIE method. The insulation layer 110 is formed of, for example, SiOx.

From this stage on, the upper wiring layer 112 made of Al, Al, Cu or the like, is formed and then selectively etched into a wiring pattern by, for example, the RIE method, and thus a magneto-resistive element having the structure shown in FIG. 5 is completed.

As described above, according to this embodiment, the cap layer 106 which has a surface tension equal to or less than that of the second ferromagnetic layer 105, is formed on the ferromagnetic layer 105 in the magneto-resistive element. With this structure, the island-like growth of the cap layer 106 can be prevented, and therefore the cap layer 106 is formed conformally on the ferromagnetic layer 105. Thus, the diffusion of the materials from the cap layer 106 to the ferromagnetic layer 105 can be suppressed, thereby preventing the degradation of the magnetic properties of the ferromagnetic layer 106. Consequently, a high MR ratio can be achieved.

Further, with selection of an alloy of a combination of an element having a standard electrode potential higher that those of Co and Fe which constitute the ferromagnetic layer 105 and an element having a lower potential, the embodiment exhibits an advantageous effect of being capable of improving the thermal resistance while maintaining the good magnetic properties. Further, Al—Ni is used as the cap layer 106, the surface tension thereof is not excessively lowered. Thus, the embodiment exhibits another advantage of being capable of preventing the island-like growth of the upper wiring layer 107 even in the case where Al, Cu or the like is used as the upper wiring layer 107.

Therefore, a magneto-resistive element with excellent properties can be realized as a memory device of an MRAM, and the availability thereof is very high.

### MODIFIED EXAMPLE

Note that the embodiments are not limited to the one explained above.

The material of the cap layer is not limited to the Al—Ni alloy, but may be replaced as needed by any of those elected from FIG. 4 described above, according to the material of the underlying ferromagnetic layer.

More specifically, it suffices if the material is of the type which has a surface tension equal to or less than that of the second ferromagnetic layer, and it can be categorized into the followings.

(1) The surface tension of the cap layer is lower than that of the element having the lowest surface tension among those constituting the second ferromagnetic layer. That is, the cap layer is made of a single elemental metal having a surface tension lower than that of the element having the lowest surface tension among those constituting the second ferromagnetic layer, or an alloy of such metals.

(2) The surface tension of the cap layer is higher than that of the element having the lowest surface tension among those constituting the second ferromagnetic layer, but lower than that of the element having the highest surface tension among those constituting the second ferromagnetic layer. That is, the cap layer is made of a single elemental metal having a surface tension higher than that of the element having the lowest surface tension among those constituting the second ferromagnetic layer, but lower than that of the element having the highest surface tension among those constituting the second ferromagnetic layer, or an alloy of such metals.

(3) The cap layer is made of an alloy of a metal having a surface tension higher than that of the element having the lowest surface tension among those constituting the second ferromagnetic layer, but lower than that of the element having the highest surface tension among those constituting the second ferromagnetic layer, and a metal having a surface tension lower than that of the element having the lowest surface tension among those constituting the second ferromagnetic layer.

(4) The cap layer is made of an alloy of a metal having a surface tension lower than that of the element having the lowest surface tension among those constituting the second ferromagnetic layer, and a metal having a surface tension higher than that of the element having the highest surface tension among those constituting the second ferromagnetic layer.

In addition, the ferromagnetic layers are not limited to CoFeB, but various types of ferromagnetic materials can be employed. When selecting the ferromagnetic material, it suffices only if the cap layer falls within the range which satisfies the conditions (1) to (4) indicated above. Further, the tunnel barrier layer is not limited to MgO, but AlN, AlON, Al₂O₃, etc. may be used.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A magneto-resistive element, comprising:
a first ferromagnetic layer formed on an underlying substrate;
a tunnel barrier layer formed on the first ferromagnetic layer;
a second ferromagnetic layer formed on the tunnel barrier layer; and
a cap layer formed on the second ferromagnetic layer,
wherein a surface tension of the cap layer is equal to or less than that of the second ferromagnetic layer.

2. The magneto-resistive element of claim 1, wherein the surface tension of the cap layer is lower than that of an element having a lowest surface tension among those elements which the second ferromagnetic layer comprises.

3. The magneto-resistive element of claim 2, wherein the cap layer is a single elemental metal having a surface tension lower than that of the element having the lowest surface tension among those elements which the second ferromagnetic layer comprises, or an alloy of such metals.

4. The magneto-resistive element of claim 3, wherein the cap layer is a single elemental metal of Al, Mn, Zn, Mg, Ag, Sn and Pb, or an alloy of a combination of any of these.

5. The magneto-resistive element of claim 3, wherein the cap layer is an alloy of one or more of Al, Mn, Zn and Mg and another one or more of Ag, Sn and Pb.

6. The magneto-resistive element of claim 1, wherein the surface tension of the cap layer is higher than that of an element having a lowest surface tension among those elements which the second ferromagnetic layer comprises, but lower than that of an element having a highest surface tension among those elements which the second ferromagnetic layer comprises.

7. The magneto-resistive element of claim 6, wherein the cap layer is a single elemental metal having a surface tension higher than that of the element having the lowest surface tension among those elements which the second ferromagnetic layer comprises, but lower than that of the element having the highest surface tension among those elements which the second ferromagnetic layer comprises, or an alloy of such metals.

8. The magneto-resistive element of claim 7, wherein the cap layer is a single elemental metal of Ti, Hf, Cr, Zr, Pt, Pd, Cu and Au, or an alloy of a combination of any of these.

9. The magneto-resistive element of claim 7, wherein the cap layer is an alloy of one or more of Ti, Hf, Cr and Zr and another one or more of Pt, Pd, Cu and Au.

10. The magneto-resistive element of claim 1, wherein the cap layer is an alloy of an element having a surface tension higher than that of an element having a lowest surface tension among those elements which the second ferromagnetic layer comprises, but lower than that of an element having a highest surface tension among those elements which the second ferromagnetic layer comprises, and another element having a surface tension lower than that of the element having the lowest surface tension among those elements which the second ferromagnetic layer comprises.

11. The magneto-resistive element of claim 10, wherein the cap layer is an alloy of one or more of Ti, Hf, Cr, Zr, Pt, Pd, Cu and Au and another one or more of Ag, Sn, Pb, Al, Mn, Zn and Mg.

12. The magneto-resistive element of claim 10, wherein the cap layer is an alloy of one or more of Ti, Hf, Cr and Zr and another one or more of Ag, Sn and Pb, or an alloy of one or more of Pt, Pd, Cu and Au and one or more of Al, Mn, Zn and Mg.

13. The magneto-resistive element of claim 1, wherein the cap layer is an alloy of an element having a surface tension lower than that of an element having a lowest surface tension among those elements which the second ferromagnetic layer comprises, and another element having a surface tension higher than that of an element having a highest surface tension among those elements which the second ferromagnetic layer comprises.

14. The magneto-resistive element of claim 13, wherein the cap layer is an alloy of one or more of Ta, V, Nb, W, Mo, Ru, Ir and Rh and another one or more of Ag, Sn, Pb, Mn, Al, Zn and Mg.

15. The magneto-resistive element of claim 13, wherein the cap layer is an alloy of one or more of Ta, V and Nb and another one or more of Ag, Sn and Pb, or an alloy of one or more of W, Mo, Ru, It and Rh and one or more of Mn, Al, Zn and Mg.

16. The magneto-resistive element of claim 1, wherein the second ferromagnetic layer comprises Fe or Co.

17. The magneto-resistive element of claim 1, further comprising an upper layer formed on the cap layer, wherein a surface tension of the cap layer is higher than that of the upper layer.

18. A magneto-resistive element, comprising:
a first ferromagnetic layer formed on an underlying substrate, the first ferromagnetic layer comprising FeCoB;
a tunnel barrier layer formed on the first ferromagnetic layer, the tunnel barrier layer comprising MgO;
a second ferromagnetic layer formed on the tunnel barrier layer, the second ferromagnetic layer comprising Fe, Co and B; and
a cap layer formed on the second ferromagnetic layer, the cap layer comprising an alloy of an element having a surface tension lower than that of Fe or Co, and another element having surface tension lower than that of B.

19. The magneto-resistive element of claim 18, wherein the cap layer is an alloy of one or more of Ti, Hf, Cr and Zr and another one or more of Ag, Sn and Pb, or an alloy of one or more of Pt, Pd, Cu and Au and one or more of Al, Mn, Zn and Mg.
